(19) United States
(12) Patent Application Publication
(10) Pub. No.: US 2009/0014050 A1
(43) Pub. Date: Jan. 15, 2009

(54) Solar module system and method using transistors for bypass

(76) Inventor: Peter Haaf, Stuttgart (DE)

Correspondence Address: SIDLEY AUSTIN LLP, 555 CALIFORNIA STREET, SUITE 2000, SAN FRANCISCO, CA, 94104-1715, US

(21) Appl. No.: 11/827,755

(22) Filed: Jul. 13, 2007

(51) Int. Cl. H01L 31/042

(52) U.S. Cl. 136/244

(57) ABSTRACT

In one embodiment, a bypass component is provided for use with a string of solar cells. Each solar cell is operable to generate power in response to light. A current may flow through all of the solar cells of the string to deliver the power generated by the solar cells of the string out to a load. The bypass component provides a bypass route for the string of solar cells in the event that at least one solar cell of the string is not generating power. The bypass component includes at least two transistors connected in series with each other and in parallel with the string of solar cells, each transistor having a control terminal. Control logic for the bypass component provides a control signal to the control terminal of each of the at least two transistors. The control signal turns on the at least two transistors so that current flows through the at least two transistors, thereby bypassing the string of solar cells, when at least one solar cell of the string is not generating power.

### BACKGROUND

1. Field of Invention

The present invention relates to solar module systems and methods, and more particularly, to a solar module system and method using transistors for bypass.

2. Description of Related Art

Solar modules convert light from the sun into electricity that can be used to power devices in homes and offices or which can be fed into the power grid. A typical implementation for a solar module system includes multiple modules, each having a string of solar cells connected in series. Each solar cell generates some amount of electrical power. Current flowing through the cells in the module transfers the electrical power of the cells out to a load (e.g., home appliance) or the power grid. If one of the cells in the solar module is shaded (i.e., covered), then no electricity is generated in that cell, and current cannot flow through the cell. Under such circumstances, because the cells are connected in series, it is necessary to bypass the shaded cell so that the electrical power generated in the remaining (un-shaded) cells can be delivered out of the module.

### SUMMARY

According to an embodiment of the present invention, a solar module system is provided. The solar module system includes a plurality of solar cells, each of which is operable to generate power in response to light. The plurality of solar cells are arranged in strings. Each string of solar cells comprising at least two solar cells connected in series. A current may flow through all of the strings of solar cells to deliver the power generated by the solar cells of each string to a load. The solar module system also includes a plurality of bypass components, with a separate bypass component being provided for each string of solar cells. Each bypass component is operable to provide a bypass route for the respective string of solar cells in the event that at least one solar cell of the respective string is not generating power. Each bypass component includes at least two transistors connected in series with each other and in parallel with the respective string of solar cells. Each transistor has a control terminal. Control logic for each bypass component provides a control signal to the control terminal of each of the at least two transistors. The control signal turns on the at least two transistors so that current flows through the at least two transistors, thereby bypassing the respective string of solar cells, when at least one solar cell of the respective string is not generating power.

According to another embodiment of the present invention, a bypass component is provided for use with a string of solar cells. Each solar cell is operable to generate power in response to light. A current may flow through all of the solar cells of the string to deliver the power generated by the solar cells of the string out to a load. The bypass component provides a bypass route for the string of solar cells in the event that at least one solar cell of the string is not generating power. The bypass component includes at least two transistors connected in series with each other and in parallel with the string of solar cells, each transistor having a control terminal. Control logic for the bypass component provides a control signal to the control terminal of each of the at least two transistors. The control signal turns on the at least two transistors so that current flows through the at least two transistors, thereby bypassing the string of solar cells, when at least one solar cell of the string is not generating power.

Important technical advantages of the present invention are readily apparent to one skilled in the art from the following figures, descriptions, and claims.

### BRIEF DESCRIPTION OF DRAWINGS

For a more complete understanding of the present invention and for further features and advantages, reference is now made to the following description taken in conjunction with the accompanying drawings.

FIG. 1 is a block diagram of a solar module system with bypass components, according to an embodiment of the invention.

FIG. 2 is an exemplary implementation for a two-legged semiconductor package for a bypass component, according to an embodiment of the invention.

FIG. 3 is an exemplary implementation of control circuitry, according to an embodiment of the invention.

FIG. 4 is an exemplary waveform diagram for operation of a bypass component, according to an embodiment of the invention.

### DETAILED DESCRIPTION

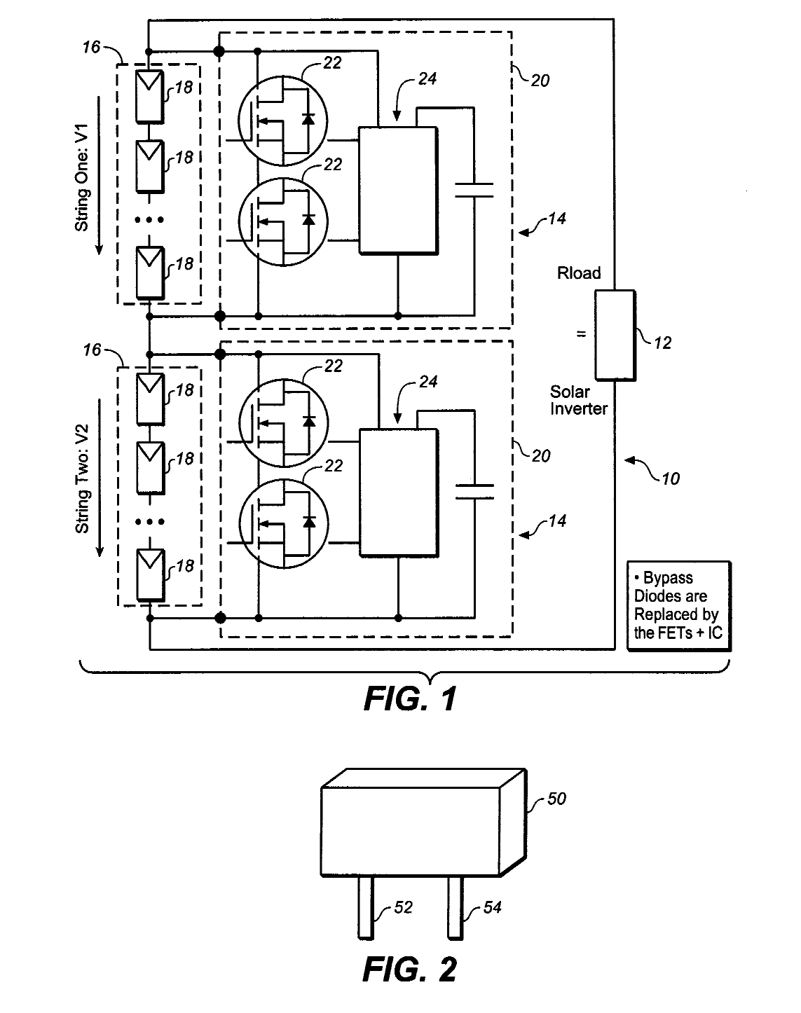

Embodiments of the present invention and their advantages are best understood by referring to FIGS. 1-4 of the drawings. Like numerals are used for like and corresponding parts of the various drawings.

FIG. 1 is a block diagram of a solar module system 10, according to an embodiment of the invention. In general, solar module system 10 generates power (e.g., voltage) in response to light and delivers the power to a load (Rload) 12, which can be, for example, a solar inverter. Solar module system 10 includes a plurality of solar modules 14 coupled together and to the load 12. As used herein, the terms “coupled” or “connected,” or any variant thereof, covers any coupling or connection, either direct or indirect, between two or more elements or components. At least some of the solar modules 14 in the system 10 may be connected in series.

Each solar module 14 comprises one or more strings 16 of solar cells 18 and a bypass component 20. For each solar module 14, the solar cells 18 in each string 16 are connected in series. Solar cells 18 can be implemented according to techniques which are understood to one of ordinary skill in the art. When exposed to light energy, each solar cell 18 in a string 16 can generate power in response thereto. To deliver power generated in the solar cells 18 out of the string 16, current may flow through the series of solar cells 18 in the string. Such current may have a magnitude of, for example, 10 A. If any solar cell 18 of a string 16 is covered or shaded (either fully or partially), such solar cell 18 may not generate power. When this occurs, current either cannot flow through the string 16 or is substantially hindered or impeded.

For each solar module 14, the bypass component 20 functions to provide or support a bypass route or circuit for current to flow through the solar module 14 when one or more of the solar cells 18 in the module 14 is covered or shaded (thus impeding current flow through the respective string 16). As depicted, each bypass component 20 comprises at least two switches or transistors 22 and control circuitry 24.

The transistors 22, of each bypass component 20, are connected in series with each other. Furthermore, the series-connected transistors 22 are connected in parallel with the respective string 16 of solar cells 18 in the solar module 14. In one embodiment, each transistor 22 can be implemented as a metal-oxide-semiconductor field effect transistor (MOSFET), although any other suitable power device (e.g., an IGBT, a MOS-gated thyristor, or JFET) can be used. Each transistor 22 has a control terminal (e.g., gate) at which a respective control signal is applied for turning on and off the respective transistor 22 so that current can flow therethrough.

Each transistor 22 can be relatively small in size, with corresponding operational parameters or characteristics. For example, a small transistor can have relatively small Rdson, such as, for example, 2 mOhms. Each transistor 22 can also have a breakdown or blocking voltage of a certain value, such as, for example, 20V. The breakdown voltage is the minimum amount of voltage which must appear across the transistor 22 before current will flow through the transistor even if the transistor is not turned on with an appropriate voltage applied at its control terminal (e.g., gate).

With the transistors 22 in the bypass component 20 connected in series, the total breakdown voltage across the transistors 22 is approximately equal to the sum of the breakdown voltages for the separate transistors. Thus, for example, if there are two transistors 22 in the bypass component 20 and each transistor 22 has a breakdown voltage of 20V, then the total breakdown voltage across the transistors 22 of the bypass component will be approximately 40V.

The control circuitry 24 for each bypass component 20 functions to provide control signals for turning on and off the respective transistors 22. The control circuitry 24 may monitor or otherwise receive some indication of whether one or more of the cells 18 of the respective string 16 are shaded or covered, and thus neither generating power nor conducting current. In one embodiment, this can be accomplished by monitoring or considering the total voltage potential across the transistors 22 of the bypass component 20, which is the same as the total voltage potential across the respective string 16 of solar cells 18 in the solar module 14.

If the total voltage potential across the string 16 of solar cells 18 in the solar module 14 does not exceed a certain threshold (which can be a predetermined value) or is not negative, then it is likely that all solar cells 18 in the string 16 are generating power and conducting current. As such, it is unnecessary to bypass current from the string 16. The control circuitry 24 outputs control signals that do not turn on the transistors 22 in the bypass component 20.

Alternately, if the total voltage potential across the string 16 of solar cells 18 in the solar module 14 exceeds the certain threshold (which can be a predetermined value) or is negative, it is likely that one or more solar cells 18 in the string 16 are covered or shaded, and thus not conducting current. The control circuitry 24 will output control signals to turn on the transistors 22. This allows current to flow through the transistors 22, thereby bypassing the respective string 16 of solar cells 18.

The use of two or more transistor 22 in each bypass component 20 provides a technical advantage relative to some previous designs, which utilized either a diode or a single transistor for bypassing current.

In a diode bypass element, power losses can be significant. For example, with a current magnitude of 10 A, a Schottky diode with a forward voltage (Vf) of 0.5V yields a power loss of 5 W (i.e., Pv=10 A*0.5V). Furthermore, the large losses generate significant heat, which must be dissipated by a heat sink. Such a heat sink increases the size and cost for implementation of the bypass element.

In a single-transistor bypass design, the drive circuit to turn the bypass transistor on is supplied by the blocking voltage of the bypass transistor, which corresponds to the voltage drop over the body diode of such transistor. Such voltage drop is relatively small (e.g., approximately 0.5V), and in itself is generally not able provide sufficient gate driving voltage for the transistor. To generate adequate gate driving voltage, it is necessary to use a self-oscillating circuit and a transformer. The transformer cannot be implemented in an integrated circuit (IC) device, but instead is typically implemented in a separate discrete device. Thus, the gate drive circuitry for a single-transistor bypass design must be implemented on a printed circuit board (PCB), which is more expensive than a fully integrated implementation. In addition, when the single transistor is driven by a simple, self-oscillating circuit, the transistor can be in linear mode (not fully turned on) during operation, which is less efficient. Furthermore, the self-oscillating circuit adds additional complexity to the implementation. Also, a large-sized transistor according to previous designs typically has a higher Rdson (e.g., 5 mOhm) than smaller-sized transistors. The higher Rdson of the large-sized transistor is also less efficient.

With the multiple-transistor implementation (using two or more transistors 22 in bypass component 20), when the bypass component 20 starts operating, the current flows through the body diodes of the bypass transistors 22. The voltage drop over two or more diodes (e.g., 1.0V or more) is at least twice that of a single-transistor bypass implementation. With such higher voltage drop, it is much easier to operate an IC which generates the gate voltages, compared to a single-transistor bypass design having only one body diode. As such, the gate driving voltages can be generated in an IC device, thus allowing for a smaller, less expensive implementation compared to the single-transistor bypass of previous designs. A PCB is not required for implementation of the bypass component 20, according to embodiments of the present invention.

In some embodiments, for example, all or a portion of each bypass component 20 can be implemented on a single or multiple semiconductor dies (commonly referred to as a “chip”). Each die is a monolithic structure formed from, for example, silicon or other suitable material. In one embodiment, for example, each bypass transistor 22 is implemented on a separate chip, and the control circuitry 24 is implemented on a yet another chip.

Furthermore, in some embodiments, all or a portion of each bypass component 20 can be contained or implemented in a single semiconductor package, which provides for a relatively small implementation in size (especially compared to a PCB implementation). Thus, for example, the chips for the bypass transistors 22 and the control circuitry 24 are contained in one semiconductor package.

In some embodiments, the single semiconductor package for bypass component 20 can have two leads (e.g., legs). This allows the bypass component 20, according to embodiments of the present invention, to be a replacement for a diode design (which itself has two legs).

In some embodiments, if a higher gate driving voltage is necessary or desired for driving the transistors 22, the supply voltage for generating the higher driving voltage may be created internally with a topology having, for example, an inverting charge pump, a inverter circuit, buck-boost circuit, or a CUK converter. A topology with a charge pump uses one or more capacitors to develop a high voltage level from a lower voltage level. In a charge pump topology for the bypass component 20, the capacitors can be integrated into the silicon of one or more of the chips or at least into the single semiconductor package. A topology with an inverter circuit uses an inductor. Such inductor can be implemented, for example, with bonding wire, thus allowing it to be also integrated into the single semiconductor package. A high frequency, DC/DC converter (e.g., with a frequency greater than 10 MHz) can be used in such inverter circuit topology to create the necessary gate-to-source voltage. Since there is low power demand and no steady operation, such a high frequency converter is easier to implement compared to standard DC/DC converters.

Furthermore, a higher supply voltage can help to more precisely control the transistors 22 of the bypass component 20. In particular, using a higher supply voltage can prevent the transistors 22 from operating in linear mode, thus enhancing or improving the performance or efficiency of the bypass component 20. This provides a technical advantage over some prior designs where the bypass transistor may operate at least part of the time in linear mode, which is less efficient.

Also, with multiple-transistor implementation (using two or more transistors 22 in bypass component 20), when there is negative current through the bypass transistors, the voltage drop over two body diodes will be doubled or greater, for example, to greater than 1.0V. This amount of voltage is sufficient for ultra-low power (ULP) logic parts to operate, thus allowing for implementation on an integrated circuit (IC) device. At the same time, other IC processes are available, which operate at voltages above 1.0V.

FIG. 2 is an exemplary implementation for a two-legged semiconductor package 50 for a bypass component 20, according to an embodiment of the invention. The package 50 has a first lead or leg 52 and a second lead or leg 54. The first lead/leg 52 may be connected to one end of the respective string 16 for the solar module 14, while the second lead/leg of the package 50 may be connected to the other end of the string 16.

The two-legged semiconductor package 50 for a bypass component 20 is possible because each of the two or more transistors 22 in bypass component 20 can be relatively small so that it can be driven with a small gate driving circuit. Such a small gate driving circuit can be implemented in an IC device. As such, in some embodiments, because the bypass component 20 can be driven with an IC device, it is not necessary to use many of the components, such as a transformer, that are typically required to generate the gate driving voltages for a single-transistor design, and which mandate a PCB implementation. Thus, the package 50 can be made relatively small. Furthermore, no additional (third) leg is required to otherwise supply a high voltage to the bypass component 20 from externally. This allows the bypass component 20, according to embodiments of the present invention, to be a replacement for a diode design (which itself has two legs).

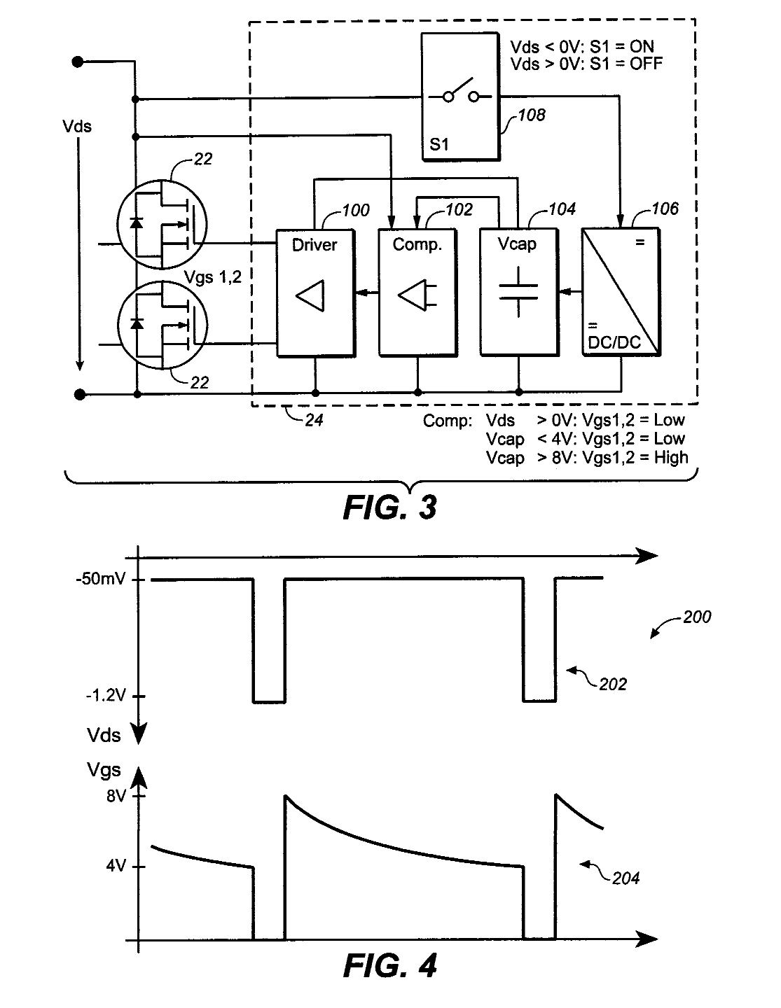

FIG. 3 is an exemplary implementation of control circuitry 24, according to an embodiment of the invention. Separate control circuitry 24 may be provided for each bypass component 20 in solar module system 10. The control circuitry 24 provides control signals for turning on and off the respective transistors 22 for the bypass component 20. As shown, in one embodiment, the control circuitry 24 comprises a driver circuit 100, a comparator 102, a capacitor 104, a DC/DC converter 106, and a switch 108.

The voltage potential across the transistors 22, which is the same as the voltage potential across the string 16 of solar cells 18, is Vds. If Vds has a value greater than 0V, then current is flowing through all solar cells 18 of the string 16. In such case, it is unnecessary for bypass component 20 to perform the bypass function. If Vds has a value of approximately 0V or less, however, then current is not flowing through all cells 18 of the string 16. This means that one or more of the solar cells 18 is covered or shaded (or otherwise not operating to generate power). In this situation, the transistors 22 of bypass component 20 should be turned on so that current may flow therethrough, thus bypassing the solar cell string 16 for the solar module 14.

Switch 108 is coupled at one end of the solar cell string 16. If Vds has a value of more than 0V, then switch 108 is turned off. Alternately, if Vds has a value of approximately 0V or less, then switch 108 is turned on. DC/DC converter 106 a lower negative voltage to a higher positive voltage. The capacitor 104 is charged by the output from DC/DC converter 106. The switch 108 connects the DC/DC converter 106 to Vds. In one embodiment, for example, if Vds is less than −1.0V, the DC/DC converter 106 can convert this voltage into a higher positive voltage and charge the capacitor 104. Capacitor 104 may provide a driving voltage for driver circuit 100.

Comparator 102 compares the voltage on capacitor 104 and outputs control signals in response. The driver circuit 100 is responsive to the signals from comparator 102. Driver circuit 100 provides drive signals for controlling the turn on and turn off of the transistors 22 of the bypass component 20. If Vds has a value of more than 0V (current is flowing through the string 16 of solar cells 18), driver circuit 100 will output control signals with values that do not turn on the transistors 22. Alternately, if Vds has a value of approximately 0V or less (current is not flowing through all cells 18 of the string 16), then driver circuit 100 will initially continue to output control signals with values that do not turn on the transistors 22 as the voltage on capacitor 104 rises from 0V.

When the voltage on capacitor 104 reaches a certain value (e.g., 8V), the comparator 102 causes driver circuit 100 to output control signals to turn on transistors 22, thus allowing current to flow therethrough and bypass the solar cell string 16.

When the Voltage on the capacitor 104 drops from 8V to another certain value (e.g., 4V), the transistors 22 stay turned on. The capacitor 104 is discharging due to current consumption of driver circuit 100, comparator 102, and other leakage currents. Then, when the voltage on capacitor 104 reaches the other value (e.g., 4V), the driver circuit 100 turns transistors 22 off in order to prevent the transistors 22 from operating in linear mode. An additional advantage of turning off the transistors 22 at a specified level is that the Rdson of a MOSFET rises as its gate voltage decreases. A higher Rdson translates into lower efficiency (or higher losses). It is desirable to control the losses, especially if no heat sink is provided.

In one embodiment, for this phase, when the transistors 22 are turned on, the voltage drop over the two transistors 22 may be relatively small (e.g., 50 mV). This voltage is connected to the input of the DC/DC converter 106, which cannot operate at such low voltage.

In the next step, when the driver circuit 100 turns the transistors 22 off, the input voltage of the DC/DC converter 106 will rise to about 1.2V due to the voltage drop over two diodes. The DC/DC converter 106 will recharge the capacitor 104 to, for example, 8V.

In one embodiment, driver circuit 100 uses the voltage stored on capacitor 104 for providing the control signals to turn on or drive transistors 22. As such, no batteries or additional wires (for example, connected to any of the solar cells) are needed to power or implement the bypass component 20. The power for driving transistors 22 is thus provided internally within bypass component 20. This allows the bypass component 20 to be compatible with existing fittings for solar cell modules that are designed for a bypass diodes.

FIG. 4 is an exemplary waveform diagram 200 for operation of a bypass component 20, according to an embodiment of the invention. Diagram 200 includes waveform 202 for the voltage drop Vds across the transistors 22 in the bypass component 20, and waveform 204 for the gate-to-source voltage (Vgs) or driving voltage of the transistors 22.

Diagram 200 shows waveforms for bypass component 20 operating to bypass solar cell string 16 when one or more of the solar cells 18 in the respective solar cell module 14 are shaded or covered, and thus not generating power.

When bypass component 20 first starts to bypass the solar cell string 16, Vds for the transistors 22 can be a first level (e.g., −1.2V). The bypass transistors 22 are turned on. Here the DC/DC converter 106, supplied by Vds greater than 1.0V, is operating to charge the capacitor 104 to higher voltage, for example, from 4V to 9V. At this start time, bypass component 20 has higher losses.

When the capacitor 104 has charged to a certain value (which can be predetermined), the capacitor 104 supplies the turn-on voltage for the bypass transistors 22. Here, Vds for the transistors 22 can be a second level (e.g., −50 mv). At this time, bypass component 20 has lower losses.

As such, the driving voltage at the gate of the transistors 22 is initially higher (e.g., approximately 8V), but decreases over time to a lower value (e.g., approximately 4V).

Although the present invention and its advantages have been described in detail, it should be understood that various changes, substitutions, and alterations can be made therein without departing from the spirit and scope of the invention as defined by the appended claims. That is, the discussion included in this application is intended to serve as a basic description. It should be understood that the specific discussion may not explicitly describe all embodiments possible; many alternatives are implicit. It also may not fully explain the generic nature of the invention and may not explicitly show how each feature or element can actually be representative of a broader function or of a great variety of alternative or equivalent elements. Again, these are implicitly included in this disclosure. Where the invention is described in device-oriented terminology, each element of the device implicitly performs a function. Neither the description nor the terminology is intended to limit the scope of the claims.

What is claimed is:

1. A solar module system comprising:
a plurality of solar cells, each solar cell operable to generate power in response to light, the plurality of solar cells arranged in strings, each string of solar cells comprising at least two solar cells connected in series, wherein a current may flow through all of the strings of solar cells to deliver the power generated by the solar cells of each string to a load; and
a plurality of bypass components, wherein a separate bypass component is provided for each string of solar cells, each bypass component operable to provide a bypass route for the respective string of solar cells in the event that at least one solar cell of the respective string is not generating power;
wherein each bypass component comprises:
at least two transistors connected in series with each other and in parallel with the respective string of solar cells, each transistor have a control terminal;
control logic for providing a control signal to the control terminal of each of the at least two transistors, the control signal for turning on the at least two transistors so that current flows through the at least two transistors, thereby bypassing the respective string of solar cells, when at least one solar cell of the respective string is not generating power.

2. The solar module system of claim 1, wherein each bypass component has at least two terminals for connection into the solar module system, the first terminal connected at one end of the respective string of solar cells, the second terminal connected at the other end of the respective string of solar cells.

3. The solar module system of claim 2, wherein each bypass component is implemented without a printed circuit board.

4. The solar module system of claim 1, wherein each bypass component is contained in a single semiconductor package.

5. The solar module system of claim 4, wherein each semiconductor package has at most two terminals for connection into the solar module system.

6. The solar module system of claim 1, wherein each bypass component comprises a power element for internally providing power to drive the at least two transistors.

7. The solar module system of claim 1, wherein each bypass component comprises one of a charge pump, an inverter circuit, a buck-boost circuit, or a CUK converter for providing a high voltage to drive the at least two transistors.

8. The solar module system of claim 7, wherein each bypass component is contained in a single semiconductor package.

9. The solar module system of claim 1, wherein each bypass component comprises a power element for providing a high voltage to drive the at least two transistors, wherein the power element comprises an inductor.

10. The solar module system of claim 9, wherein the inductor is implemented with bonding wire.

11. The solar module system of claim 10, wherein each bypass component is contained in a single semiconductor package.

12. The solar module system of claim 7, wherein each bypass component is implemented in an integrated circuit device.

13. The solar module system of claim 1, wherein the control signal provided to the control terminal of each of the at least two transistors prevents each of the at least two transistors from operating in linear mode.

14. The solar module system of claim 1, wherein the at least one solar cell of the respective string is not generating power because the at least one solar cell is covered.

15. The solar module system of claim 1, wherein each bypass component is implemented without a printed circuit board.

16. A bypass component for use with a string of solar cells, each solar cell operable to generate power in response to light, wherein a current may flow through all of the solar cells of the string to deliver the power generated by the solar cells of the string out to a load, the bypass component for providing a bypass route for the string of solar cells in the event that at least one solar cell of the string is not generating power, the bypass component comprising:
at least two transistors connected in series with each other and in parallel with the string of solar cells, each transistor have a control terminal; and
control logic for providing a control signal to the control terminal of each of the at least two transistors, the control signal for turning on the at least two transistors so that current flows through the at least two transistors, thereby bypassing the string of solar cells, when at least one solar cell of the string is not generating power.

17. The bypass component of claim 16, comprising:
a first terminal for connection at one end of the string of solar cells; and
a second terminal for connection at the other end of the string of solar cells.

18. The bypass component of claim 16, wherein the bypass component is implemented without a printed circuit board.

19. The bypass component of claim 16, wherein the bypass component is contained in a single semiconductor package.

20. The bypass component of claim 19, wherein the semiconductor package has at most two external terminals.

21. The bypass component of claim 16, comprising a power element for internally providing power to drive the at least two transistors.

22. The bypass component of claim 16, comprising one of a charge pump, an inverter circuit, a buck-boost circuit, or a CUK converter for providing a high voltage to drive the at least two transistors.

23. The bypass component of claim 22, wherein the bypass component is contained in a single semiconductor package.

24. The bypass component of claim 22, wherein the bypass component is implemented in an integrated circuit device.

25. The bypass component of claim 16, comprising a power element for providing a high voltage to drive the at least two transistors, the power element having an inductor.

26. The bypass component of claim 25, wherein the inductor is implemented with bonding wire.

27. The bypass component of claim 26, wherein the bypass component is contained in a single semiconductor package.

28. The bypass component of claim 16, wherein the control signal provided to the control terminal of each of the at least two transistors prevents each of the at least two transistors from operating in linear mode.

29. The bypass component of claim 16, wherein the bypass component is implemented without a printed circuit board.
